(19) United States
(12) Patent Application Publication
(10) Pub. No.: US 2012/0002452 A1
(43) Pub. Date: Jan. 5, 2012

(54) Compact inverter

(76) Inventor: Guil Hetzroni, Coral Springs, FL (US)

(21) Appl. No.: 12/826,990

(22) Filed: Jun. 30, 2010

(51) Int. Cl. H02M 7/537; H05K 3/30

(52) U.S. Cl. 363/131; 29/832

(57) ABSTRACT

A method of making a compact power inverter is disclosed. Steps include: providing a plurality of transistors, a main circuit board, a transformer, an input control circuit board; an output control circuit board; and optionally, casing; aligning transistors in the plurality of transistors in rows on the top side of the main circuit board; capping the rows with heat sinks; installing the main circuit board in the casing when a casing is present, preferably in a thermally coupled configuration adapted to cool at least one of the transistors in the plurality of transistors by conduction to the casing; positioning the output control circuit board and the input control circuit board vertically between rows of the plurality of transistors; and, attaching the transformer to the bottom side of the main circuit board.

### TECHNICAL FIELD

In the field of electric power conversion systems, a method of manufacturing a compact inverter to convert direct current to alternating current and control the output voltage using transistor control means in the line circuit, the operation of which is controlled by condition responsive means.

### BACKGROUND ART

Modern inverters are typically solid state electrical devices that convert electric power from direct current to alternating current using transistors for switching. Inverters produce alternating current controlled for voltage and frequency with the use of appropriate transformers, switching components, and control circuits.

Typically, the switching component is an Insulated Gate Field Effect Transistor, which controls the flow of current using an electrical field applied at a contact, called the gate. The gate is electrically isolated from the current-carrying medium. Metal Oxide Semiconductor Field Effect Transistor, or MOSFET, uses a metal gate made with silicon dioxide that serves as an insulator. Such gates are now usually manufactured using polysilicon. However, MOSFET is typically used in the industry, and also in this application, to refer to any Insulated Gate Field Effect Transistor. When the term transistor is used in this application, it is intended to be used with a broad definition to refers in general to a semiconductor switch, a MOSFET and/or an Insulated Gate Field Transistor, which are herein considered equivalent terms.

A single circuit board for an inverter typically comprises the inverter switching and output control circuits, transistors (switches), heat sinks, and transformer, which are dispersed on a single side of the main circuit board. The transformer is spatially removed from the locations of the switches to facilitate heat dissipation at both locations. Conduction and forced air flow over the components of the inverter enable heat removal from the inverter components.

This arrangement requires a large casing to hold the main circuit board and the greater the power conversion, the larger the casing.

### SUMMARY OF INVENTION

A method of making a compact power inverter for converting direct current to alternating current, as well as the inverter resulting from such method, are disclosed. The method includes a first step of providing the necessary components for an inverter, namely, transistors; a main circuit board comprising a top side and a bottom side; a transformer; an input control circuit board; an output control circuit board; and, preferably, a casing comprising a top wall and two side walls, the side walls adapted to connect to the top wall to form two corners. Other steps include aligning transistors in the plurality of transistors in rows on the top side of the main circuit board; capping the rows of transistors with one or more heat sinks, wherein each heat sink is attached to at least one row of transistors; installing the main circuit board in the casing when a casing is present and then, preferably in a thermally coupled configuration adapted to cool at least one of the transistors in the plurality of transistors by conduction to the casing; positioning the output control circuit board and the input control circuit board vertically between rows of the plurality of transistors; and, attaching the transformer to the bottom side of the main circuit board.

### Technical Problem

Inverters need to be made smaller for multiple applications, but this requires overcoming spatial separation of inverter components considered necessary in traditional inverter design. The standard inverter circuit board layout consists of MOSFETs installed on both right and left size of the casing, in order to use the casing to cool the inverter components. This layout functions well, but it necessitates an elongated casing. The other components which require additional a larger area of separation are the transformers and the input and output control circuits. Yet, the standard requirement is that the transformers be placed in proximity of the input MOSFET due to high current being transferred between the two.

### Solution to Problem

The solution is a method of manufacture that enables more efficient cooling of the inverter components. The method aligns MOSFETs in multiple parallel rows on the top side of a circuit board enabling cooling from one end of the casing to the other end by air transit down the corridor between the rows plus additional heat sinks placed directly on top of the MOSFETS and at least one MOSFET thermally connected to the casing when a casing is used and that casing is metal. In an alternative embodiment typically using a non-metallic casing, there is no thermal connection to the casing. Each transformer is located on the underside of the main circuit board to further reduce the space required on the main circuit board, and to position them in close proximity to the MOSFETs to limit the length of current transit. Finally, an input control circuit board and an output control circuit board are configured approximately perpendicularly to the main circuit board to physically offset them from the other components on the main circuit board and to improve cooling.

### Advantageous Effects of Invention

The method results in manufacturing a physically smaller inverter, enhancing the value and usefulness of devices powered by the conversion of direct current to alternating current. It has its most dramatic size-reduction effect on large inverters over about 1000 Watts, reducing them in size by up to about 60 percent. However, the method disclosed will reduce the physical dimensions of any wattage inverter.

### BRIEF DESCRIPTION OF DRAWINGS

The drawings illustrate preferred embodiments of the method of the invention and inverters made using this method. The reference numbers in the drawings are used consistently throughout. New reference numbers in FIG. 2 are given the 200 series numbers. Similarly, new reference numbers in each succeeding drawing are given a corresponding series number beginning with the figure number.

FIG. 1 is a flow diagram of a preferred method of the invention.

FIG. 2 is a perspective view of the top side of the main circuit board made using the method of the invention.

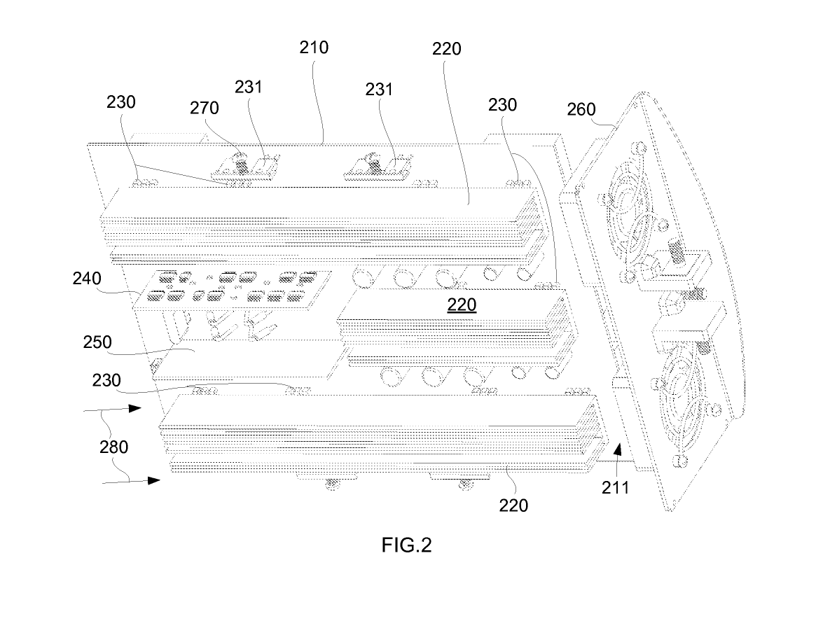

FIG. 3 is a perspective view of the bottom side of the main circuit board made using the method of the invention.

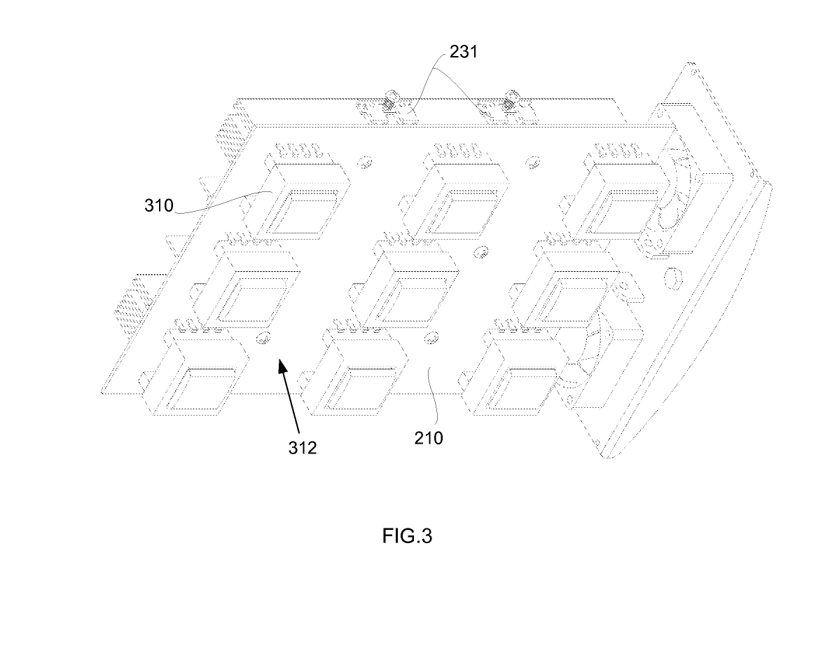

FIG. 4 is a perspective view of a second end of an alternative embodiment of the main circuit board using the method of the invention.

FIG. 5 is a perspective view of the first end of the main circuit board inside a casing made using the method of the invention.

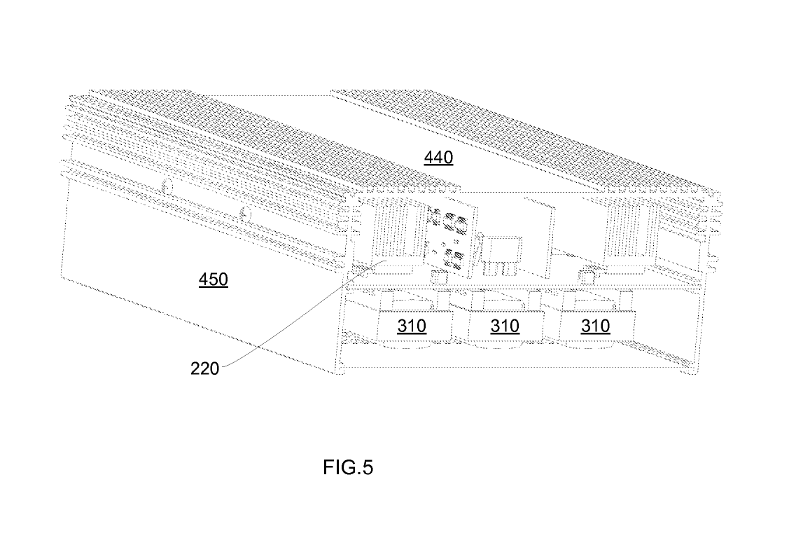

FIG. 6 is a flow diagram of an alternative preferred method of the invention.

### DESCRIPTION OF EMBODIMENTS

In the following description, reference is made to the accompanying drawings, which form a part hereof and which illustrate preferred embodiments of the present invention. The drawings and the preferred embodiments of the invention are presented with the understanding that the present invention is susceptible of embodiments in many different forms and, therefore, other embodiments may be utilized and structural, and operational changes may be made, without departing from the scope of the present invention. For example, the steps in the method of the invention may be performed in any order that results making the inverter.

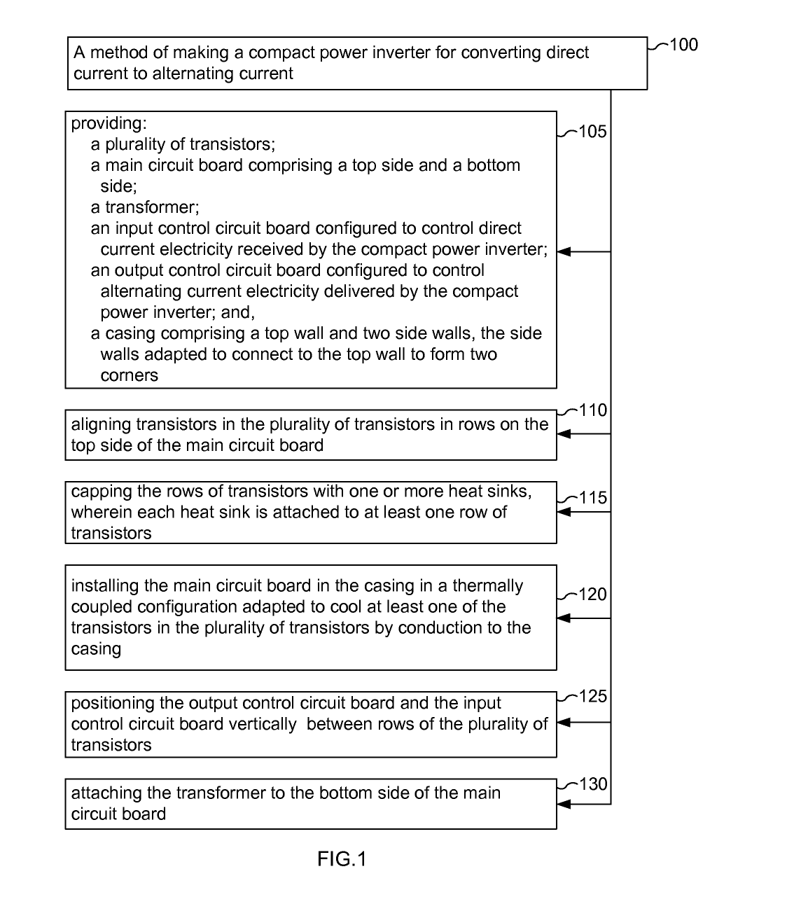

FIG. 1 illustrates the steps involved in a preferred method of making the inverter (100). Six steps are included in this method of making the inverter (100): a providing step (105); an aligning step (110); a capping step (115); an installing step (120); a positioning step (125); and an attaching step (130).

The providing step (105) is more specifically providing a plurality of transistors (230), each of which is a semiconductor switch, such as a MOSFET or other Insulated Gate Field Transistor.

The providing step (105) further includes providing a main circuit board (210). The main circuit board (210) is any suitable board for hosting circuits and components therefor, comprising a top side (211) and a bottom side (312).

The providing step (105) further includes providing a transformer (310). The invention includes using more than one transformer (310). A plurality of transformers is likely required for inverters delivering 400 watts or more of alternating current, but multiple transformers may be used on smaller or higher wattage inverters. Such transformers are well known in the art.

The providing step (105) further includes providing an input control circuit board (240) configured to control direct current electricity received by the compact power inverter. The input control circuit board (240) regulates the direct current voltage received by the inverter. The input control circuit board (240) is a separate printed circuit board capable of being positioned on the main circuit board (210).

The providing step (105) further includes providing an output control circuit board (250) configured to control alternating current electricity delivered by the compact power inverter. The output control circuit board (250) regulates the alternating current and frequency of produced by the inverter. The output control circuit board (250) is a separate printed circuit board capable of being positioned on the main circuit board (210).

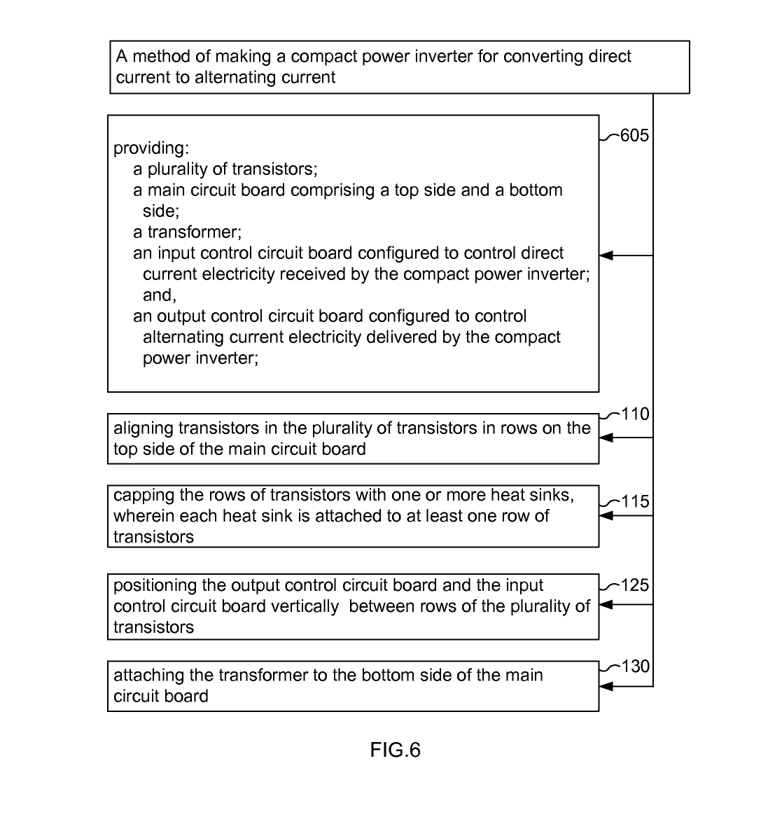

The providing step (105) optionally and preferably includes providing a casing (430) to house the other components provided in this step. The invention will reduce the size of an inverter whether or not a casing is used; and so, a casing is optional, such as in applications where the inverter will be housed in box provided by a user. Thus, the alternative embodiment diagrammed in FIG. 6 shows a providing step (605) with no mention of the casing. However, for most 30 applications a casing (430) will be provided, as shown in FIG. 1. When provided, the casing (430) includes at least a top wall (440) and two side walls (450). The side walls (450) are adapted to connect to the top wall (440) to form two corners (431). The casing (430) may include other walls as well, for example a bottom wall (432), depending on the application.

The casing (430) is preferably made of a metal and includes fins (433) extending outwardly from the top wall (440). The fins (433) preferably extend from the corners (431) between the top wall (440) and the side walls (450). The casing (430) further preferably includes fins (433) that extend inwardly on the side walls (450). In an alternative embodiment, the casing is made of a non-metallic material, such as plastic.

The aligning step (110) is more specifically aligning transistors (230) in the plurality of transistors in rows on the top side (211) of the main circuit board (210). This is preferably an orderly array of adjacent rows and columns occupying usable space on top side (211) of the main circuit board (210). The rows are separated by a suitable distance to permit air flow (280) on both sides of the transistors (230), or more particularly between the rows of transistors, by convection or forced flow such as from a fan unit (260), or by a combination of convection and forced air flow.

The capping step (115) is more specifically capping the rows of transistors (230) with one or more heat sinks, wherein each heat sink (220) is attached to at least one row of transistors (230). An electrically insulating tape is preferably used to electrically isolate each heat sink (220) from the transistors (230), yet permit heat to flow by conduction from the transistors (230) to the heat sink (220).

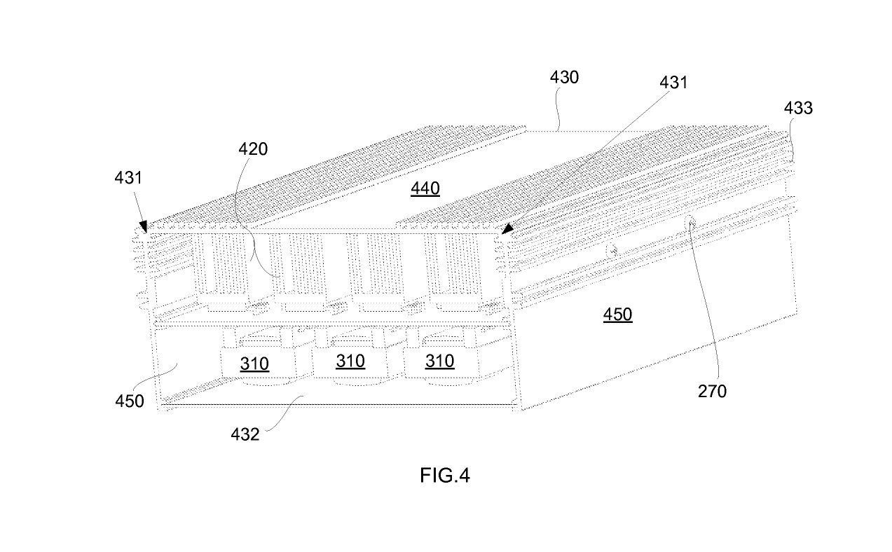

A single heat sink (220) may be used atop all of the transistors, or, preferably a single heat sink (220) on each row of transistors (230). The latter preserves the separation of the rows of transistors (230) and increases the surface area of the heat sink (230) exposed to air flow (280) across the transistors (230). Each heat sink (220) is preferably of the finned variety that enables air flow 30 between the fins for maximum heat transfer away from the heat sink to the air flow (280). As shown in FIG. 4, the top of at least one heat sink (220) capping the transistors (230) may be in physical contact with the top wall (440) of the casing (430) to promote thermal conduction away from the heat sink (220) to the casing (430) and thence to the surrounding environment. This embodiment makes sense when a metal casing is provided that is capable of promoting thermal conduction.

The installing step (120) is preferable, but optional because a casing (430) does not have to be provided. This is illustrated in FIG. 6, where the installing step (120) is omitted. This installing step (120) is more specifically installing the main circuit board (210) in the casing (430) in a thermally coupled configuration adapted to cool at least one of the transistors (231) in the plurality of transistors by conduction to the casing (430). This configuration is preferably one in which at least one of the transistors (231), or a heat conductor physically in contact with such transistors, is in direct contact with the casing (430), preferably through an attachment bolt (270), preferably 4 such attachment bolts. Other arrangements involving some physical contact between any of the transistors (230 or 231) in the plurality of transistors and the casing, or something connected to the transistors and the casing, is within the scope of the invention.

In an alternative embodiment, the installing step (120) is more specifically installing the main circuit board (210) in the casing (430). In this embodiment, the casing may be made of a non-metallic material where there is little thermal conduction from any of the transistors in the plurality of transistors to the casing.

The positioning step (125) is more specifically positioning the output control circuit board (250) and the input control circuit board (240) vertically between rows of the plurality of transistors (230). The output control circuit (250) and the input control circuit board (240) are each on their own printed circuit board, which is located vertically to maximize heat transfer in a configuration perpendicular to the main circuit board (210) holding the transistors (230) and the transformer (310).

The attaching step (130) is more specifically attaching the transformer (230) to the bottom side (312) of the main circuit board (210). Each transformer (310) is preferably attached so that its length is along the same path as the length of each heat sink (220). This creates a passage between each transformer (310) for air flow in the same direction as the air flow (280) between each heat sink (220), when multiple heat sinks are used.

The above-described embodiments including the drawings are examples of the invention and merely provide illustrations of the invention. Other embodiments will be obvious to those skilled in the art. Thus, the scope of the invention is determined by the appended claims and their legal equivalents rather than by the examples given.

### INDUSTRIAL APPLICABILITY

The invention has application to the power conversion industry.

What is claimed is:

1. A method of making a compact power inverter for converting direct current to alternating current, the method comprising the steps of:
providing:
a plurality of transistors;
a main circuit board comprising a top side and a bottom side;
a transformer;
an input control circuit board configured to control direct current electricity received by the compact power inverter;
an output control circuit board configured to control alternating current electricity delivered by the compact power inverter; and,
a casing comprising a top wall and two side walls, the side walls adapted to connect to the top wall to form two corners;
aligning transistors in the plurality of transistors in rows on the top side of the main circuit board;
capping the rows of transistors with one or more heat sinks, wherein each heat sink is attached to at least one row of transistors;
installing the main circuit board in the casing in a thermally coupled configuration adapted to cool at least one of the transistors in the plurality of transistors by conduction to the casing;
positioning the output control circuit board and the input control circuit board vertically between rows of the plurality of transistors; and,
attaching the transformer to the bottom side of the main circuit board.

2. The method of making a compact power inverter of claim 1, wherein at least one heat sink capping the rows of transistors is in physical contact with the top wall of the casing.

3. A compact power inverter for converting direct current to alternating current made by the method of claim 1.

4. A method of making a compact power inverter for converting direct current to alternating current, the method comprising the steps of:
providing:
a plurality of transistors;
a main circuit board comprising a top side and a bottom side;
a transformer;
an input control circuit board configured to control direct current electricity received by the compact power inverter; and,
an output control circuit board configured to control alternating current electricity delivered by the compact power inverter;
aligning transistors in the plurality of transistors in rows on the top side of the main circuit board;
capping the rows of transistors with one or more heat sinks, wherein each heat sink is attached to at least one row of transistors;
positioning the output control circuit board and the input control circuit board vertically between rows of the plurality of transistors; and,
attaching the transformer to the bottom side of the main circuit board.

5. A compact power inverter for converting direct current to alternating current made by the method of claim 4.
